(19) United States
(12) Patent Application Publication
(10) Pub. No.: US 2020/0296312 A1
(43) Pub. Date: Sep. 17, 2020

(54) BUFFERING CIRCUIT FOR SENSED SIGNAL AND RELATED IMAGE SENSOR

(71) Applicants: Egis Technology Inc., Taipei (TW); Igistec Co., Ltd., Hsinchu County (TW)

(72) Inventors: YU HSUAN LIN, Hsinchu County (TW); CHUNG YI WANG, Hsinchu County (TW)

(21) Appl. No.: 16/661,997

(22) Filed: Oct. 23, 2019

Related U.S. Application Data
(60) Provisional application No. 62/816,956, filed on Mar. 12, 2019.

(30) Foreign Application Priority Data
Sep. 19, 2019 (CN) 201910886637.8

(51) Int. Cl. H04N 5/378; H03F 3/08

(52) U.S. Cl. CPC H04N 5/378; H03F 2200/228; H03F 2200/267; H03F 3/082

(57) ABSTRACT

A buffering circuit arranged to buffer a sensed signal of a pixel circuit includes: an amplifying circuit, a first switching unit and a capacitor. The amplifying circuit has a control terminal of coupled to an output terminal of the pixel circuit, a first terminal arranged to output a buffered sensed signal, and a second terminal coupled to a reference voltage. The first switching unit has a first terminal coupled to the control terminal of the amplifying circuit and a second terminal coupled to the first terminal of the amplifying circuit. The capacitor has a first terminal coupled to the control terminal of the amplifying circuit and a second terminal coupled to the first terminal of the amplifying circuit. The first switching unit is turned on during a first stage and turned off during a second stage. The amplifying circuit generates the buffered sensed signal during the second stage.

### CROSS REFERENCE TO RELATED APPLICATIONS

This application claims the benefit of U.S. Provisional Application No. 62/816,956, filed on Mar. 12, 2019. The entire contents of the related applications are incorporated herein by reference.

### BACKGROUND OF THE INVENTION

### 1. Field of the Invention

The present invention relates generally to image sensing, and more particularly, to a buffering circuit for buffering sensed signals of pixel circuits and related image sensor.

### 2. Description of the Prior Art

Typically, sensed signals generated by pixel circuits are read by a readout circuit. Before a sensed signal is read by the readout circuit, a buffering circuit is employed for buffering the sensed signal. Please refer to FIG. 1, which is a diagram illustrating structure and application regarding a buffering circuit in the conventional art. As illustrated, a sensed signal V_sensed at a terminal VX of a pixel circuit 10 is buffered by a buffering circuit 20, a buffered sensed signal V_buffered is accordingly generated at a terminal VXS and then read by a readout circuit 13. In a reset stage, the terminal VX is connected to a specific voltage level through a switching unit SW2, such that a voltage level of the sensed signal V_sensed will rise to the specific voltage level. In a sense stage, the switching unit SW2 is turned off and a capacitor C_S is discharged through a photo detecting element 12, such that the voltage level of the terminal VX deviates from the specific voltage level gradually. In a readout stage, the switching unit SW1 is turned on, and the readout circuit 13 reads the buffered sensed signal V_buffered. However, under some undesired illumination conditions (e.g. pool light intensity or short exposure time), changes in the sensed signal V_sensed will be pretty minor and thus it would be difficult to precisely reflect the illumination condition of the pixel circuit 10.

### SUMMARY OF THE INVENTION

In order to address the above-mentioned problems, it is one object of the present invention to provide a buffering circuit for buffering sensed signals of pixel circuits. The buffering circuit of the present invention includes a common-source amplifier. With the common-source amplifier, changes in the sensed signal can be effectively enlarged, thereby to reflect the illumination condition better. In view of this, the present invention substantially leads to an improvement on the sensitivity of the pixel circuit.

According to embodiment, a buffering circuit that is arranged to buffer a sensed signal of a pixel circuit is provided. The buffering circuit comprises: an amplifying circuit, a first switching unit and a capacitor. A control terminal of the amplifying circuit is coupled to an output terminal of the pixel circuit, a first terminal of the amplifying circuit is arranged to output a buffered sensed signal, and a second terminal of the amplifying circuit is coupled to a reference voltage. The first switching unit has a first terminal and a second terminal. The first terminal of the first switching unit is coupled to the control terminal of the amplifying circuit and the second terminal of first switching unit is coupled to the first terminal of the amplifying circuit. The capacitor has a first terminal and a second terminal. The first terminal of the capacitor is coupled to the control terminal of the amplifying circuit. The second terminal of the capacitor is coupled to the first terminal of the amplifying circuit. Additionally, the first switching unit is arranged to turn on during a first stage and turn off during a second stage. The amplifying circuit is arranged to generate the buffered sensed signal during the second stage.

According to embodiment, an image sensor is provided. The image sensor comprises a pixel circuit array and at least one buffering circuit. The pixel circuit array has a plurality of pixel circuits. The at least one buffering circuit is arranged to buffer a sensed signal of at least one of the plurality of pixel circuits. The at least one buffering circuit comprises: an amplifying circuit, a first switching unit and a capacitor. A control terminal of the amplifying circuit is coupled to an output terminal of the pixel circuit, a first terminal of the amplifying circuit is arranged to output a buffered sensed signal, and a second terminal of the amplifying circuit is coupled to a reference voltage. The first switching unit has a first terminal and a second terminal. The first terminal of the first switching unit is coupled to the control terminal of the amplifying circuit and the second terminal of first switching unit is coupled to the first terminal of the amplifying circuit. The capacitor has a first terminal and a second terminal. The first terminal of the capacitor is coupled to the control terminal of the amplifying circuit. The second terminal of the capacitor is coupled to the first terminal of the amplifying circuit. Additionally, the first switching unit is arranged to turn on during a first stage and turn off during a second stage. The amplifying circuit is arranged to generate the buffered sensed signal during the second stage.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a diagram illustrating structure and application regarding a buffering circuit of the conventional art.

FIG. 2 is a diagram illustrating structure and application regarding a buffering circuit according to one embodiment of the present invention.

FIGS. 3-5 are diagrams illustrating operations of the buffering circuit according to embodiments of the present invention.

FIG. 6 is a diagram illustrating structure and application regarding a buffering circuit according to another embodiment of the present invention.

FIG. 7 is a diagram illustrating an image sensor according to one embodiment of the present invention.

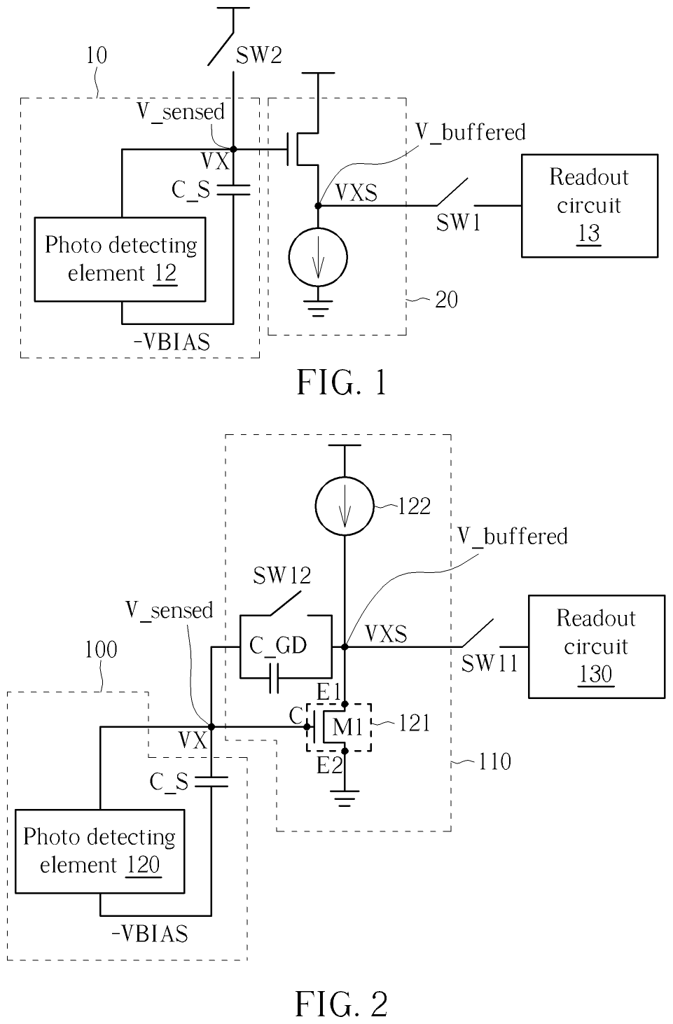

### DETAILED DESCRIPTION

Certain terms are used throughout the following descriptions and claims to refer to particular system components. As one skilled in the art will appreciate, manufacturers may refer to a component by different names. This document does not intend to distinguish between components that differ in name but not differ in functionality. In the following discussion and in the claims, the terms “include”, “including”, “comprise”, and “comprising” are used in an open-ended fashion, and thus should be interpreted to mean “including, but not limited to . . . ” The terms “couple” and “coupled” are intended to mean either an indirect or a direct electrical connection. Thus, if a first device couples to a second device, that connection may be through a direct electrical connection, or through an indirect electrical connection via other devices and connections.

Different features of the present invention are detailed as below in reference to the figures, and for convenience of explanation, the same elements in separate figures are indicated by the same reference numerals. Moreover, reference throughout this specification to “one embodiment” means that a particular feature, structure or characteristic described in connection with the embodiment or example is included in at least one embodiment of the present embodiments. Thus, appearances of the phrases “in one embodiment”, in various places throughout this specification are not necessarily all referring to the same embodiment or example. Furthermore, the particular features, structures or characteristics may be combined in any suitable combinations and/or sub-combinations in one or more embodiments or examples.

Please refer to FIG. 2, which illustrates a circuit diagram of a buffering circuit in accordance with one embodiment of the present invention. As illustrated, a pixel circuit 100 includes a photo detecting element 120 and parasitic capacitance C_S. The photo detecting element 120 is sensitive to illumination and impedance thereof varies with the intensity of the illumination. According to various embodiments of the present invention, the photo detecting element 120 could be a photoresistor, a photodiode or any element that is sensitive to illumination and its impedance varies with the intensity of the illumination. The present invention is not limited in scope to types of the photo detecting elements. The pixel circuit 100 is coupled to the buffering circuit 110. The buffering circuit 110 is arranged to buffer a sensed signal V_sensed at an output terminal VX of the pixel circuit 100, thereby to output the buffered sensed signal V_buffered at a terminal VXS. The buffering circuit 110 comprises an amplifying circuit 121, a switching unit SW12, a capacitor C_GD and a current source 122. According to various embodiments of the present invention, the amplifying circuit 121 could comprise one or more transistors. The amplifying circuit 121 includes a control terminal C, a first terminal E1 and a second terminal E2. The control terminal C of the amplifying circuit 121 is coupled to the switching unit SW12 and a first terminal of the capacitor C_GD. The first terminal E1 of the amplifying circuit 121 is coupled to the current source 122, the switching unit SW12 and a second terminal of the capacitor C_GD. The second terminal E2 of the amplifying circuit 121 is coupled to ground (or a reference voltage). Please note that, even though the amplifying circuit 121 is described as comprising only one transistor in the following, this is not a limitation of the present invention. In this embodiment, the amplifying circuit 121 comprises a transistor M1 set in common-source configuration. Specifically, a gate of the transistor M1 is coupled to the control terminal C of the amplifying circuit 121, a drain of the transistor M1 is coupled to the first terminal E1 of the amplifying circuit 121 and a source of the transistor M1 is coupled to the second terminal E2 of the amplifying circuit 121.

Although the amplifying circuit 121 of FIG. 2 only includes a transistor M1, the amplifying circuit 121 may further include one or more active/passive components (e.g. transistors, capacitors or resistors) according to various embodiments. For example, the amplifying circuit 121 could include multiple transistors that are connected and set in cascode configuration as well as common-source configuration.

In one embodiment, the capacitor C_GD could implemented by parasitic capacitances between the control terminal C and the first terminal E1 of the amplifying circuit 121. In the embodiment of FIG. 2, for example, the amplifying circuit 121 only comprises the transistor M1 and thus the capacitor C_GD could be parasitic capacitances between a gate terminal and a drain terminal of the transistor M1. In one embodiment, the buffering circuit 110 is coupled to the readout circuit 130 through the switching unit SW11. When the switching unit SW11 is turned on, the readout circuit 130 reads the buffered sensed signal V_buffered at the terminal VXS.

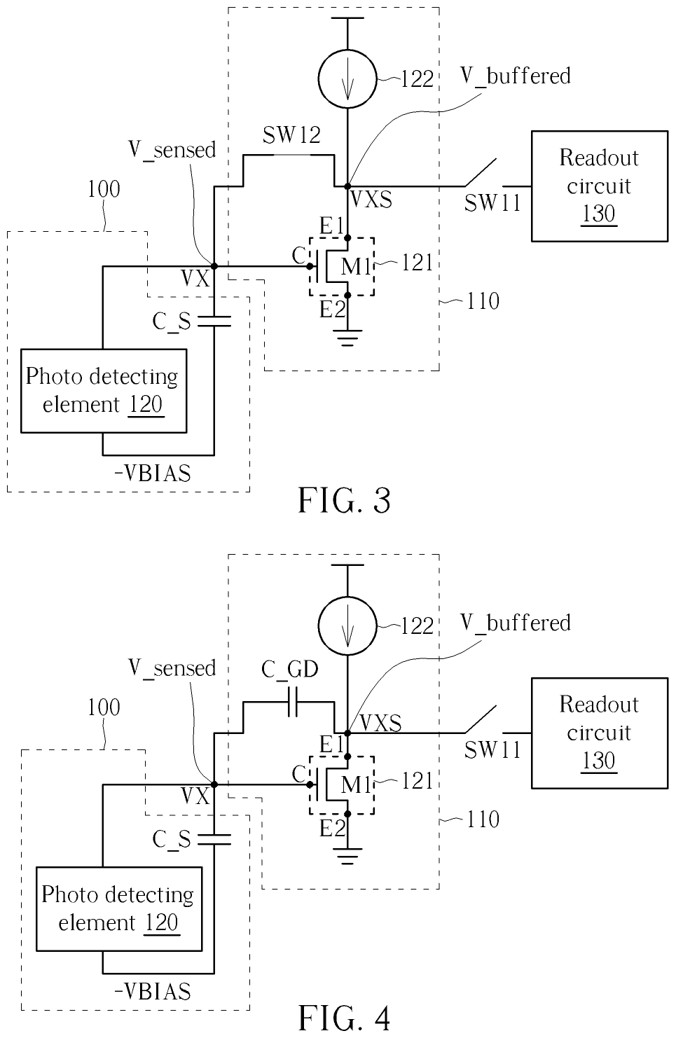

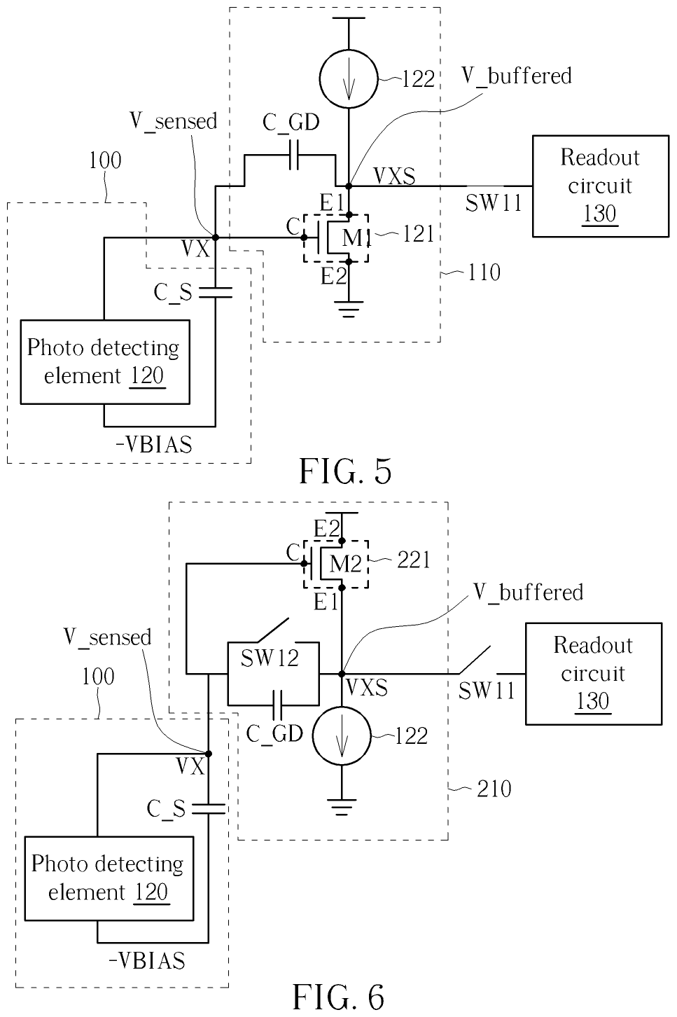

FIGS. 3-5 are diagrams illustrating detailed operations of the buffering circuit 110. In a reset stage shown by FIG. 3, the switching unit SW12 of the buffering circuit 110 is turned on, which connects the terminal VX to the terminal VXS. Accordingly, the current source 122 provides the current to the pixel circuit 100 and charges the parasitic capacitance C_S in the pixel circuit 100, such that the voltage levels of the terminals VX and VXS get identical. In a sense stage as shown in FIG. 4, the switching unit SW12 of the buffering circuit 110 is turned off, the photo detecting element 120 in the pixel circuit 100 produces current in response to the illumination. Accordingly, the parasitic capacitance C_S is discharged through the photo detecting element 120, which causes a decrease in the voltage level of the terminal VX. As the voltage level of the terminal VX drops down, the conductivity of the transistor M1 is reduced, which allows the voltage level of the terminal VXS to rise up. In one embodiment, assuming that the change in the voltage level of the terminal VX is ΔV, the change in the voltage level of the terminal VXS will thus be (C_{S}/(C_{GD}))*ΔV, where C_{S} and C_{GD} refer to capacitances of the capacitors C_S and C_GD, respectively. By properly controlling the amount of the capacitance of the capacitor C_GD, it is possible to make the ratio of C_{S}/C_{GD} greater than 1. As a subsequence, the change in the voltage level of the terminal VXS could be greater than the change in the voltage level of the terminal VX. In a readout stage shown in FIG. 5, the switching unit SW11 is turned on, such that the readout circuit 130 reads the buffered sensed signal V_buffered from the terminal VXS. Since the buffering circuit 110 enlarges the amount of the sensed signal V_sensed, the change in the voltage level of the terminal VXS will become more significant than the change in the voltage level of the terminal VX. Therefore, the readout circuit 130 could grasp the illumination condition more easily.

FIG. 6 illustrates an amplifying circuit based on a transistor of a different conductivity type in accordance with another embodiment of the present invention. In a buffering circuit 210 shown in FIG. 6, an amplifying circuit 221 comprises a P-type transistor M2 set in common-source configuration. Since principles and operations of the buffering circuit 210 are similar to those of the buffering circuit 110, further explanations are omitted here for the sake of brevity.

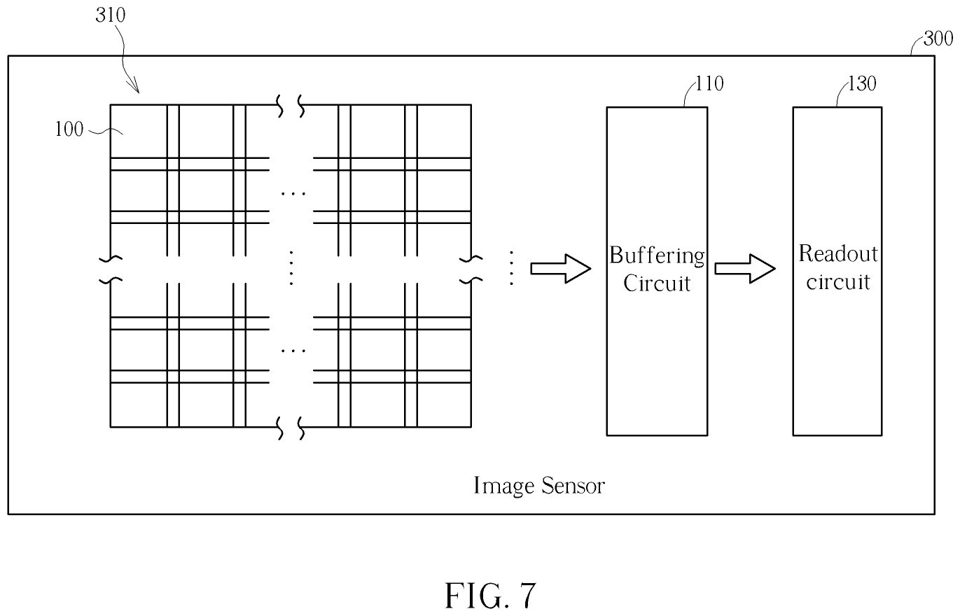

FIG. 7 illustrates an image sensor 300 in accordance with one embodiment of the present invention. As illustrated, the image sensor 300 comprises a pixel circuit array 310, which is formed by a plurality of pixel circuits 100. The image sensor 300 further comprises one or more buffering circuits 110. The one or more buffering circuits 110 are arranged to enlarge the amount of the sensed signal of the pixel circuits 100. Through one or more readout circuit 130, a buffered sensed signal is read from the buffering circuit 110. The present invention utilizes the buffering circuit 110 to perform signal amplification, which leads to an improvement on the sensitivity of the image sensor 300.

An advantage of the present invention is that the amplifying circuit in the buffering circuit is implemented based on a common-source amplifier rather than a common-drain amplifier generally used in the conventional architecture. In one embodiment, as the common-source amplifier has a greater voltage gain than the common-drain amplifier, the buffering circuit of the present invention could effectively enlarge the sensed signal outputted by the pixel circuit. On the other hand, the change in the buffered sensed signal is in inversely proportional to the amount of the parasitic capacitance C_S in the conventional architecture. Therefore, it is necessary to scale down the parasitic capacitance C_S if the sensed signal needs to be enlarged. However, scaling down the parasitic capacitance C_S also needs to scale down the size of the photo detecting element, which will inevitably lead to degradation of the sensitivity of the pixel circuit. In the present invention, the existence of the capacitor C_GD could exclude the influence of the parasitic capacitance C_S. That is, the change in the buffered sensed signal will become in inversely proportional to the amount of the capacitance of the capacitor C_GD. As the amount of the capacitance of the capacitor C_GD is not associated with the size of the photo detecting element, scaling down the capacitance of the capacitor C_GD will not affect the sensitivity of the pixel circuit. In other words, the present invention could effectively enlarge the change in the sensed signal without degrading the sensitivity of the pixel circuit, such that the following processing circuit could grasp the illumination condition more easily. Thus, the buffering circuit of the present invention could substantially lead to an improvement on the performance of the image sensor.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A buffering circuit arranged to buffer a sensed signal of a pixel circuit, comprising:
an amplifying circuit, a control terminal of the amplifying circuit being coupled to an output terminal of the pixel circuit, a first terminal of the amplifying circuit arranged to output a buffered sensed signal, and a second terminal of the amplifying circuit being coupled to a reference voltage;
a first switching unit, having a first terminal coupled to the control terminal of the amplifying circuit and having a second terminal coupled to the first terminal of the amplifying circuit; and
a capacitor, having a first terminal coupled to the control terminal of the amplifying circuit and having a second terminal coupled to the first terminal of the amplifying circuit;
wherein the first switching unit is turned on during a first stage and turned off during a second stage; the amplifying circuit is arranged to generate the buffered sensed signal during the second stage.

2. The buffering circuit of claim 1, wherein the amplifying circuit is set in common-source configuration.

3. The buffering circuit of claim 1, wherein the buffering circuit comprises a current source; the current source is coupled to the second terminal of the amplifying circuit, and the current source is arranged to provide a current to the pixel circuit during the first stage.

4. The buffering circuit of claim 1, wherein the capacitor is parasitic capacitance between the control terminal and the first terminal of the amplifying circuit.

5. The buffering circuit of claim 1, wherein the buffering circuit is coupled to a readout circuit through a second switching unit; and when the second switching unit is turned on, the readout circuit is coupled to the first terminal of the amplifying circuit and arranged to read the buffered sensed signal.

6. An image sensor, comprising:
a pixel circuit array having a plurality of pixel circuits; and
at least one buffering circuit, arranged to buffer a sensed signal of at least one of the plurality of pixel circuits, comprising:
an amplifying circuit, a control terminal of the amplifying circuit being coupled to an output terminal of the pixel circuit, a first terminal of the amplifying circuit arranged to output a buffered sensed signal, and a second terminal of the amplifying circuit being coupled to a reference voltage;
a first switching unit, having a first terminal coupled to the control terminal of the amplifying circuit and having a second terminal coupled to the first terminal of the amplifying circuit;
a capacitor, having a first terminal coupled to the control terminal of the amplifying circuit and having a second terminal coupled to the first terminal of the amplifying circuit;
wherein the first switching unit is turned on during a first stage and turned off during a second stage; and the amplifying circuit is arranged to generate the buffered sensed signal during the second stage.
